(19) United States
(12) Patent Application Publication
(10) Pub. No.: US 2026/0143733 A1
(43) Pub. Date: May 21, 2026

(54) NITRIDE SEMICONDUCTOR TRANSISTOR AND METHOD OF MANUFACTURING NITRIDE SEMICONDUCTOR TRANSISTOR

(71) Applicant: SUMITOMO ELECTRIC INDUSTRIES, LTD., Osaka (JP)

(72) Inventor: Takahiko KAWAHARA, Osaka (JP)

(21) Appl. No.: 19/365,711

(22) Filed: Oct. 22, 2025

(30) Foreign Application Priority Data
Nov. 15, 2024 (JP) 2024-199877

(51) Int. Cl. H10D 30/47; H10D 30/01; H10D 62/824

(52) U.S. Cl. CPC H10D 30/475; H10D 30/015; H10D 62/824

(57) ABSTRACT

A nitride semiconductor transistor includes a channel layer and a first barrier layer overlapping the channel layer, the first barrier layer containing a rare earth group III element, aluminum, and nitrogen. The first barrier layer includes a first region having a first oxygen concentration equal to or less than 20 at.%, and a second region having a second oxygen concentration greater than 20 at.%. The first region is located between the channel layer and the second region. A thickness of the first region is greater than that of the second region. A maximum value of the second oxygen concentration is equal to or less than 50 at.%.

### CROSS-REFERENCE TO RELATED APPLICATIONS

This application claims priority to Japanese Patent Application No. 2024-199877, filed November 15, 2024, the entire content of which is incorporated herein by reference.

### BACKGROUND

### 1. TECHNICAL FIELD

The present disclosure relates to a nitride semiconductor transistor and a method of manufacturing a nitride semiconductor transistor.

### 2. Description of Related Art

A high electron mobility transistor (HEMT) having a barrier layer containing scandium has been proposed.

Patent Document 1: PCT Japanese Translation Patent Publication No. 2024-507149

Patent Document 2: PCT Japanese Translation Patent Publication No. 2024-529722

Non-patent Document 1: A. J. Green et al., “RF Power Performance of Sc(Al,Ga)N/GaN HEMTs at Ka-band”, IEEE Electron Device Letters 41 (2019), 1181-1184

Non-patent Document 2: I. Streicher et al., “Understanding Interfaces in AlScN/GaN Heterostructures”, Advanced Functional Materials (2024), 2403027

### SUMMARY

A nitride semiconductor transistor according to the present disclosure includes a channel layer and a first barrier layer overlapping the channel layer, the first barrier layer containing a rare earth group III element, aluminum, and nitrogen. The first barrier layer includes a first region having a first oxygen concentration equal to or less than 20 at.% (atomic percent), and a second region having a second oxygen concentration greater than 20 at.%. The first region is located between the channel layer and the second region. A thickness of the first region is greater than that of the second region. A maximum value of the second oxygen concentration is equal to or less than 50 at.%.

### BRIEF DESCRIPTION OF THE DRAWINGS

FIG. 1 is a cross-sectional view illustrating a nitride semiconductor transistor according to an embodiment;

FIG. 2 is a cross-sectional view (1) illustrating a method of manufacturing the nitride semiconductor transistor according to the embodiment;

FIG. 3 is a cross-sectional view (2) illustrating the method of manufacturing the nitride semiconductor transistor according to the embodiment;

FIG. 4 is a cross-sectional view (3) illustrating the method of manufacturing the nitride semiconductor transistor according to the embodiment;

FIG. 5 is a cross-sectional view (4) illustrating the method of manufacturing the nitride semiconductor transistor according to the embodiment;

FIG. 6 is a cross-sectional view (5) illustrating the method of manufacturing the nitride semiconductor transistor according to the embodiment;

FIG. 7 is a cross-sectional view (6) illustrating the method of manufacturing the nitride semiconductor transistor according to the embodiment;

FIG. 8 is a graph showing a temperature dependence of an Hall effect before annealing;

FIG. 9 is a graph showing a temperature dependence of an Hall effect after annealing;

FIG. 10 is a graph illustrating a band structure before annealing;

FIG. 11 is a graph illustrating a band structure after annealing;

FIG. 12 is an annular dark field (ADF) image before annealing;

FIG. 13 is a bright field (BF) before annealing;

FIG. 14 is a graph illustrating a result of an energy dispersive X-ray spectroscopy (EDX) analysis before annealing;

FIG. 15 is an ADF image after annealing;

FIG. 16 is a BF image after annealing;

FIG. 17 is a graph illustrating a result of an EDX analysis after annealing;

FIG. 18 is a transmission electron microscopy (TEM) observation image before annealing;

FIG. 19 is a TEM observation image after annealing;

FIG. 20 is a schematic diagram (1) illustrating changes in structure in crystalline regions before and after annealing;

FIG. 21 is a schematic diagram (2) illustrating changes in structure in crystalline regions before and after annealing; and

FIG. 22 is a graph illustrating a relationship between a sheet carrier concentration and mobility in each annealing atmosphere.

### DETAILED DESCRIPTION

Recently, there has been a growing demand for further reduction of sheet resistance.

An object of the present disclosure is to provide a nitride semiconductor transistor capable of reducing sheet resistance and a method of manufacturing the nitride semiconductor transistor.

According to the present disclosure, sheet resistance can be decreased.

### <Description of Embodiments of Disclosure>

First, aspects of the present disclosure are listed below.

<1> A nitride semiconductor transistor according to an aspect of the present disclosure includes a channel layer and a first barrier layer overlapping the channel layer, the first barrier layer containing a rare earth group III element, aluminum, and nitrogen, and the first barrier layer includes a first region having a first oxygen concentration equal to or less than 20 at.% (atomic percent), and a second region having a second oxygen concentration greater than 20 at.%, the first region is located between the channel layer and the second region, a thickness of the first region is greater than that of the second region, and a maximum value of the second oxygen concentration is equal to or less than 50 at.%.

The first barrier layer is formed, for example, by a sputtering method, and unavoidably has a first region 1 having a first oxygen concentration equal to or less than 20 at.% and a second region 2 having a second oxygen concentration greater than 20 at.%, and the thickness of the first region 1 is greater than that of the second region 2. Since the maximum value of the second oxygen concentration is equal to or less than 50 at.%, the negative fixed charge contained in the first barrier layer is small, and the sheet resistance can be reduced.

<2> In <1>, a maximum value of the second oxygen concentration may be equal to or less than 40 at.%. In this case, the sheet resistance can be further reduced.

<3> In <1> or <2>, the nitride semiconductor transistor may further include a second barrier layer located between the channel layer and the first barrier layer, and the second barrier layer may contain gallium, aluminum, and nitrogen. In this case, the concentration of a two-dimensional electron gas can be increased, and the sheet resistance can be further reduced.

<4> In any one of <1> through <3>, the first barrier layer contains scandium as a rare earth group III element. Scandium has a relatively small ionic radius among the rare earth group III elements, and nitrides of scandium and aluminum can have a smaller lattice mismatch with gallium nitride than when other rare earth group III elements are contained. In this case, the crystallinity of the channel layer and the first barrier layer can be improved.

<5> A method of manufacturing the nitride semiconductor transistor according to another aspect of the present disclosure includes forming a channel layer and a semiconductor layer overlapping the channel layer, and forming a first barrier layer by annealing the semiconductor layer so as to lower an oxygen concentration in the semiconductor layer, and the semiconductor layer is formed by a sputtering method, and the semiconductor layer contains a rare earth group III element, aluminum, and nitrogen.

The first barrier layer formed by a sputtering method and containing a rare earth group III element, aluminum, and nitrogen unavoidably contains oxygen. By annealing the semiconductor layer so as to lower the oxygen concentration in the semiconductor layer and thereby form the first barrier layer, it is possible to reduce negative fixed charge contained in the first barrier layer and reduce sheet resistance.

<6> In <5>, the semiconductor layer may be formed at a temperature equal to or lower than 700°C. In this case, the semiconductor layer tends to have a wurtzite crystal structure.

<7> In <5> or <6>, the annealing temperature may be higher than the temperature at which the semiconductor layer is formed. In this case, the oxygen concentration of the semiconductor layer can be easily reduced.

<8> In <7>, the annealing temperature may be equal to or lower than 1,000°C. In this case, it is possible to make the phase separation caused by annealing less likely to occur in the semiconductor layer.

<9> In any one of <5> through <8>, the annealing may be performed in an atmosphere containing at least one gas selected from nitrogen gas, hydrogen gas, and ammonia gas. In this case, the oxygen concentration of the semiconductor layer can be easily reduced.

### <Details of Embodiments of Disclosure>

Embodiments of the present disclosure will be described in detail below, but the present disclosure is not limited those embodiments. In the specification and the drawings, components having substantially the same functional configuration may be denoted by the same reference numerals, thereby eliminating redundant descriptions. In the present disclosure, a “plan view” means viewing an object from above. In the present disclosure, the direction in which a nitride semiconductor layer is positioned as seen from a substrate is referred to as “above”.

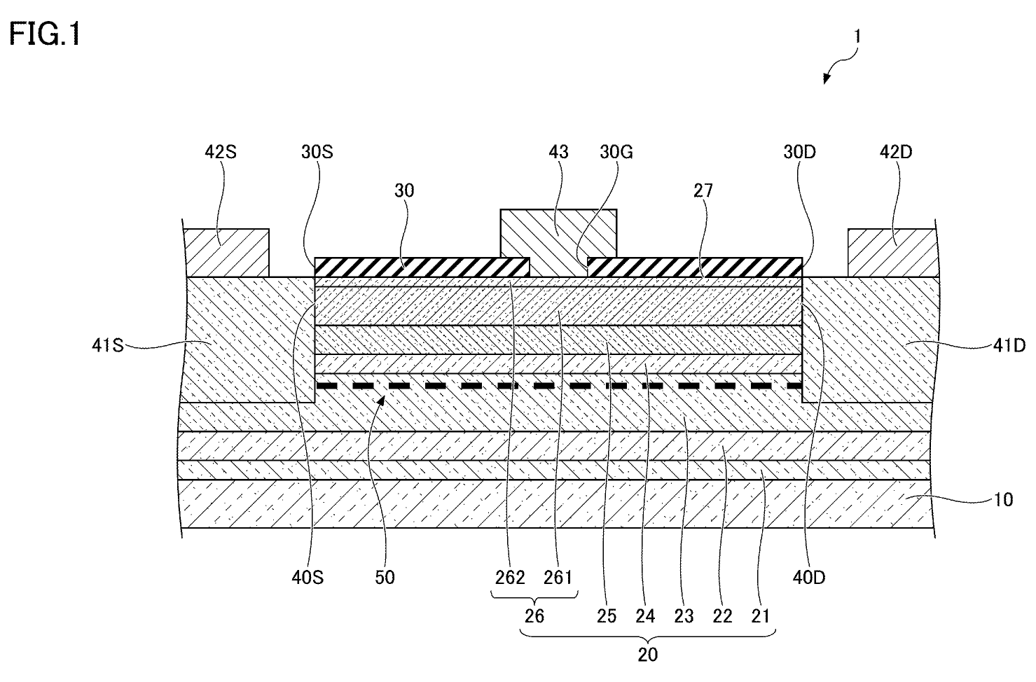

An embodiment of the present disclosure relates to a nitride semiconductor transistor. The nitride semiconductor transistor is, for example, a gallium nitride-based high electron mobility transistor (HEMT). FIG. 1 is a cross-sectional view illustrating a nitride semiconductor transistor according to the embodiment.

As illustrated in FIG. 1, a nitride semiconductor transistor 1 according to the embodiment includes a substrate 10, a nitride semiconductor layer 20, an insulating film 30, a regrowth layer 41S, a regrowth layer 41D, a gate electrode 43, a source electrode 42S, and a drain electrode 42D.

The substrate 10 is, for example, a semi-insulating silicon carbide (SiC) substrate. In the case where the substrate 10 is a SiC substrate, the upper surface of the substrate 10 is a silicon (Si) polar surface.

The nitride semiconductor layer 20 includes a nucleation layer 21, a buffer layer 22, a channel layer 23, a spacer layer 24, a second barrier layer 25, and a first barrier layer 26. For example, the buffer layer 22 is formed on the nucleation layer 21, and the channel layer 23 is formed on the buffer layer 22. The direction in which each layer is formed on another layer is also referred to as a “stacking direction”. The above-described “plan view” includes viewing an object along the stacking direction.

The nucleation layer 21 is on the substrate 10. The nucleation layer 21 is, for example, an aluminum nitride (AlN) layer. The thickness of the nucleation layer 21 is, for example, equal to or greater than 5 nm (nanometers) and equal to or less than 40 nm.

The buffer layer 22 is on the nucleation layer 21. The buffer layer 22 is, for example, a gallium nitride (GaN) layer. The buffer layer 22 may contain iron (Fe) as an impurity. The thickness of the buffer layer 22 is, for example, equal to or greater than 100 nm and equal to or less than 1,000 nm.

The channel layer 23 is on the buffer layer 22. The channel layer 23 is, for example, a gallium nitride (GaN) layer. The thickness of the channel layer 23 is, for example, equal to or greater than 10 nm and equal to or less than 1,000 nm. The conductivity type of the channel layer 23 is, for example, n-type or undoped (i-type). The buffer layer 22 and the channel layer 23 need not be distinguished.

The spacer layer 24 is on the channel layer 23. The spacer layer 24 is, for example, an aluminum nitride (AlN) layer. The thickness of the spacer layer 24 is, for example, equal to or greater than 0.5 nm and equal to or less than 3 nm.

The second barrier layer 25 is on the spacer layer 24. The second barrier layer 25 overlaps the channel layer 23. The second barrier layer 25 is, for example, an aluminum gallium nitride (AlGaN) layer. The electron affinity of the second barrier layer 25 is smaller than that of the channel layer 23. The band gap of the second barrier layer 25 is larger than that of the channel layer 23. The thickness of the second barrier layer 25 is, for example, equal to or greater than 1 nm and equal to or less than 20 nm. The composition of the second barrier layer 25 is, for example, Al_{Y}Ga_{1-Y}N (0.15 ≤ Y ≤ 0.55). In other words, in the AlGaN layer, the ratio of the number of Al atoms to the total number of Al atoms and Ga atoms (Al composition ratio) is equal to or greater than 15% and equal to or less than 55%. The conductivity type of the second barrier layer 25 is, for example, n-type or undoped (i-type).

The first barrier layer 26 is on the second barrier layer 25. The first barrier layer 26 overlaps the channel layer 23 and the second barrier layer 25. The first barrier layer 26 contains a rare earth group III element, aluminum, and nitrogen. The first barrier layer 26 is, for example, an aluminum scandium nitride (ScAlN) layer. The electron affinity of the first barrier layer 26 is smaller than that of the channel layer 23. The band gap of the first barrier layer 26 is larger than that of the channel layer 23. The thickness of the first barrier layer 26 is, for example, equal to or greater than 5 nm and equal to or less than 80 nm. The composition of the first barrier layer 26 is, for example, Sc_{X}Al_{1-X}N (0.05 ≤ X ≤ 0.45). In other words, in the ScAlN layer, the ratio of the number of Sc atoms to the total number of Al atoms and Sc atoms (Sc composition ratio) is equal to or greater than 5% and equal to or less than 45%. The first barrier layer 26 has a wurtzite crystal structure, and the crystal orientation perpendicular to an upper surface 27 of the first barrier layer 26 is [001] (c-axis). The conductivity type of the first barrier layer 26 is, for example, n-type or undoped (i-type).

The first barrier layer 26 has, in the stacking direction, a first region 261 having a first oxygen concentration and a second region 262 having a second oxygen concentration. The first region 261 is located between the channel layer 23 and the second region 262. The thickness of the first region 261 is greater than that of the second region 262. The upper surface 27 of the first barrier layer 26 is located in the second region 262. The first barrier layer 26 unavoidably contains oxygen (O), and the second oxygen concentration is greater than the first oxygen concentration. The first oxygen concentration is equal to or less than 20 at.%, and the second oxygen concentration is greater than 20 at.%. A maximum value of the second oxygen concentration is equal to or less than 50 at.%. For example, the thickness of the first region 261 is equal to or greater than 3 nm and equal to or less than 75 nm, and the thickness of the second region 262 is equal to or greater than 2 nm and equal to or less than 5 nm.

In the nitride semiconductor layer 20, a recess 40S for source and a recess 40D for drain are formed. The recess 40S and the recess 40D penetrate the first barrier layer 26, the second barrier layer 25, and the spacer layer 24. The recess 40S and the recess 40D may further penetrate the channel layer 23. The bottom of the recess 40S and the bottom of the recess 40D may be in the channel layer 23 or in the buffer layer 22.

The insulating film 30 is on the first barrier layer 26. The insulating film 30 is, for example, a silicon nitride (SiN) film. The thickness of the insulating film 30 is, for example, equal to or greater than 20 nm and equal to or less than 700 nm. An opening 30S for source, an opening 30D for drain, and an opening 30G for gate are formed in the insulating film 30. The opening 30S and the recess 40S communicate, and the opening 30D and the recess 40D communicate. In a plan view, the opening 30G is located between the opening 30S and the opening 30D. The opening 30G reaches the first barrier layer 26.

In the recess 40S, the regrowth layer 41S is on the channel layer 23 or the buffer layer 22. In the recess 40D, the regrowth layer 41D is on the channel layer 23 or the buffer layer 22. The regrowth layer 41S and the regrowth layer 41D are, for example, n-type GaN layers. The regrowth layer 41S and the regrowth layer 41D contain germanium (Ge) or silicon (Si) as n-type impurities.

The source electrode 42S is on the regrowth layer 41S, and the drain electrode 42D is on the regrowth layer 41D. The source electrode 42S is in contact with the regrowth layer 41S, and the drain electrode 42D is in contact with the regrowth layer 41D. The source electrode 42S has an ohmic contact with the regrowth layer 41S, and the drain electrode 42D has an ohmic contact with the regrowth layer 41D.

In a plan view, the gate electrode 43 is located between the source electrode 42S and the drain electrode 42D. The gate electrode 43 is on the insulating film 30 and in contact with the first barrier layer 26 via the opening 30G.

In the nitride semiconductor transistor 1, a two-dimensional electron gas (2DEG) 50 is generated in the vicinity of the upper surface of the channel layer 23 by an action of the second barrier layer 25 and the first barrier layer 26, as illustrated in FIG. 1.

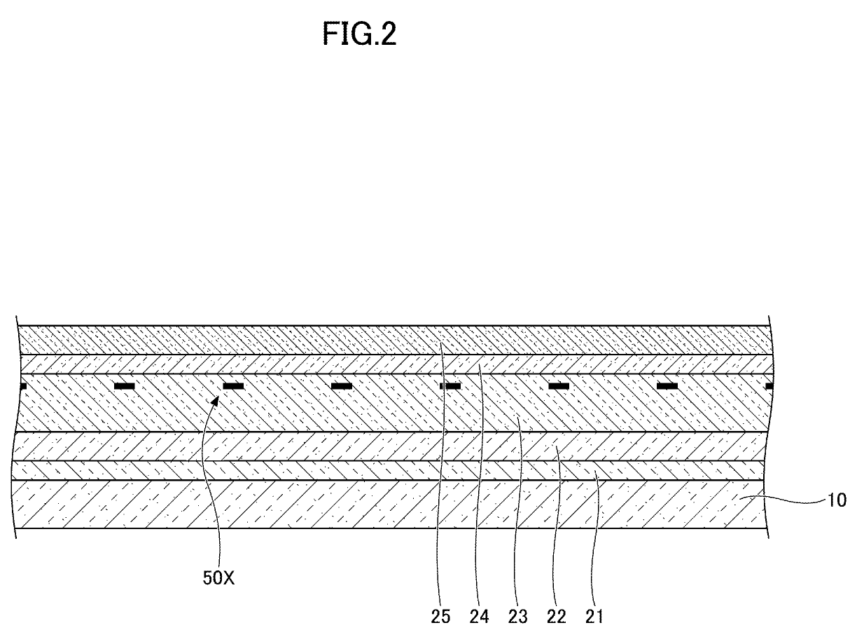

Next, a method of manufacturing the nitride semiconductor transistor according to the embodiment will be described. FIGS. 2 through 7 are cross-sectional views illustrating a method of manufacturing the nitride semiconductor transistor 1 according to the embodiment.

First, as illustrated in FIG. 2, the nucleation layer 21, the buffer layer 22, the channel layer 23, the spacer layer 24, and the second barrier layer 25 are formed on the substrate 10 in this order by, for example, a metal organic vapor phase epitaxy (MOVPE) method. The nucleation layer 21, the buffer layer 22, the channel layer 23, the spacer layer 24, and the second barrier layer 25 may be formed by an electron beam epitaxy (MBE) method.

To form the nucleation layer 21, trimethylaluminum (TMA) and ammonia (NH₃) are used as source gases, the growth temperature (formation temperature) is set to about 1,000°C, and the growth pressure (formation pressure) is set to about 5 kPa, for example. To form the buffer layer 22, trimethylgallium (TMG) and ammonia (NH₃)) are used as source gases, the growth temperature is set to about 1,000°C, and the growth pressure is set to about 40 kPa, for example. To add iron (Fe) to the buffer layer 22, cyclopentadienyl iron (Cp₂Fe) is used as a source of iron, for example. To form the channel layer 23, trimethylgallium (TMG) and ammonia (NH₃) are used as source gases, the growth temperature is set to about 1,000°C, and the growth pressure is set to about 20 kPa, for example. To form the spacer layer 24, trimethylaluminum (TMA) and ammonia (NH₃) are used as source gases, the growth temperature is set to about 1,000°C, and the growth pressure is set to about 5 kPa, for example. To form the second barrier layer 25, trimethylgallium (TMG), trimethylaluminum (TMA), and ammonia (NH₃) are used as source gases, the growth temperature is set to about 1,000°C, and the growth pressure is set to about 5 kPa, for example. When the second barrier layer 25 is formed, a two-dimensional electron gas 50X is generated in the vicinity of the upper surface of the channel layer 23.

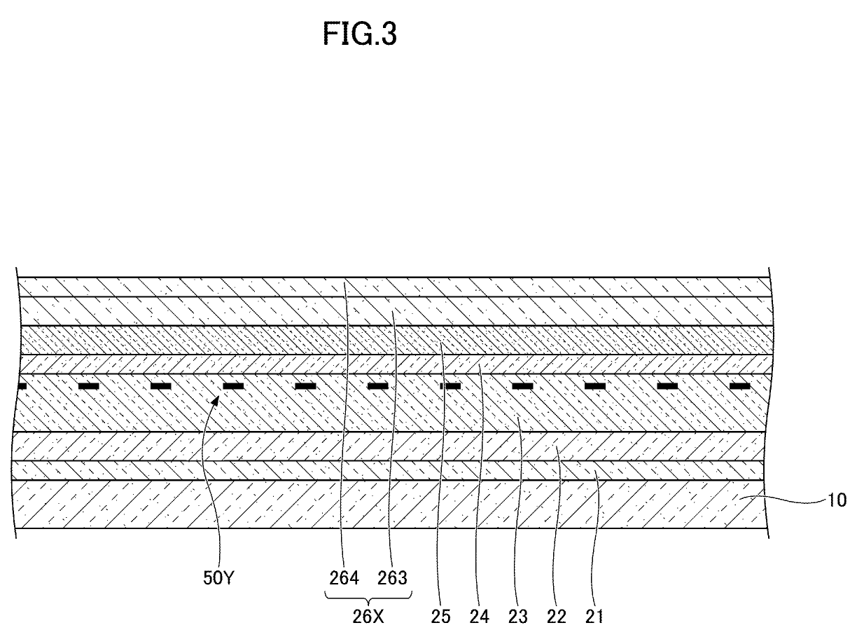

Next, as illustrated in FIG. 3, a semiconductor layer 26X, which is to become the first barrier layer 26, is formed on the second barrier layer 25 by a sputtering method. The semiconductor layer 26X contains a rare earth group III element, aluminum, and nitrogen. To form the semiconductor layer 26X, a scandium (Sc) target and an aluminum (Al) target are used, a growth temperature is set to about 650°C, and a growth pressure is set to about 10 Pa in a mixed gas atmosphere of nitrogen (N₂) and argon (Ar), for example. The semiconductor layer 26X has, in the stacking direction, a third region 263 having a third oxygen concentration and a fourth region 264 having a fourth oxygen concentration. The third region 263 is located between the channel layer 23 and the fourth region 264. The semiconductor layer 26X unavoidably contains oxygen (O), and the fourth oxygen concentration is greater than the third oxygen concentration. The third oxygen concentration is equal to or less than 30 at.%, and the fourth oxygen concentration is greater than 30 at.%. For example, the fourth oxygen concentration is greater than 30 at.% and lower than 70 at.%. A maximum value of the fourth oxygen concentration may be greater than 50 at.%. The fourth region 264 is an amorphous region. The thickness of the third region 263 need not be equal to the thickness of the first region 261, and the thickness of the fourth region 264 need not be equal to the thickness of the second region 262. When the semiconductor layer 26X is formed, a two-dimensional electron gas 50Y having a greater concentration than the two-dimensional electron gas 50X is generated in the vicinity of the upper surface of the channel layer 23.

Next, the semiconductor layer 26X is annealed so as to make the concentration of oxygen contained in the semiconductor layer 26X lower than that before the annealing. Annealing is performed, for example, in a MOVPE furnace. The atmosphere gas for annealing includes, for example, nitrogen (N₂) gas, hydrogen (H₂) gas or ammonia (NH₃) gas. The atmosphere for annealing may be a mixed atmosphere including two or more of these gases. For example, the temperature of annealing is about 800° and the time is about 60 minutes. Rapid thermal annealing (RTA) for about 10 minutes may be repeated six times.

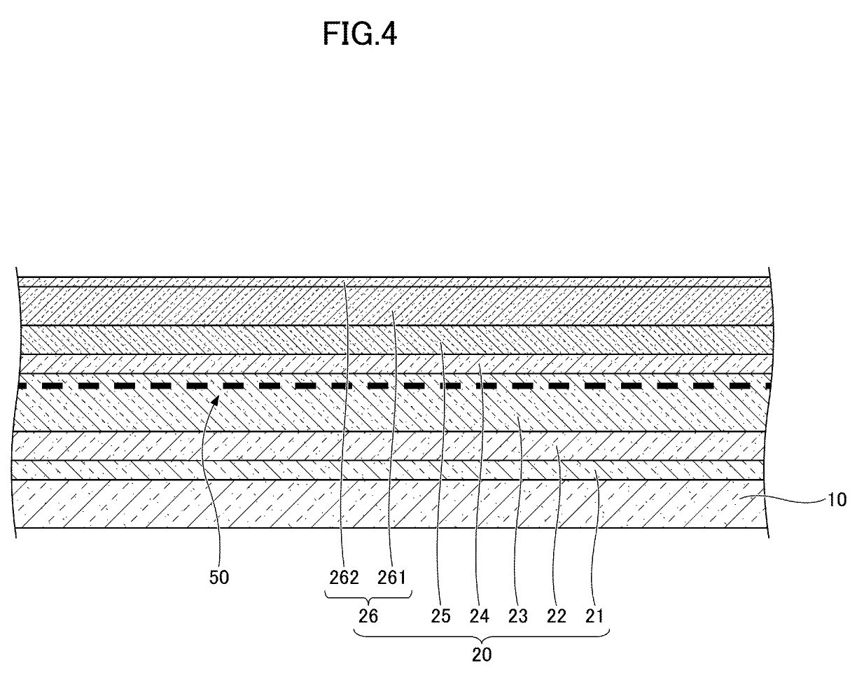

Annealing of the semiconductor layer 26X promotes crystallization of the semiconductor layer 26X. For this reason, some of the oxygen atoms contained in the fourth region 264 are discharged to the outside. Some of the oxygen atoms contained in the third region 263 diffuse to the fourth region 264 or are further discharged to the outside. As a result, as illustrated in FIG. 4, the first barrier layer 26 is obtained from the semiconductor layer 26X. The first barrier layer 26 has the first region 261 and the second region 262. When the oxygen atoms are discharged, the oxygen concentration of the first barrier layer 26 becomes lower than that of the semiconductor layer 26X. The maximum value of the second oxygen concentration in the second region 262 becomes equal to or less than 50 at.%. When the first barrier layer 26 is formed, a two-dimensional electron gas 50 having a greater concentration than the two-dimensional electron gas 50Y is generated in the vicinity of the upper surface of the channel layer 23.

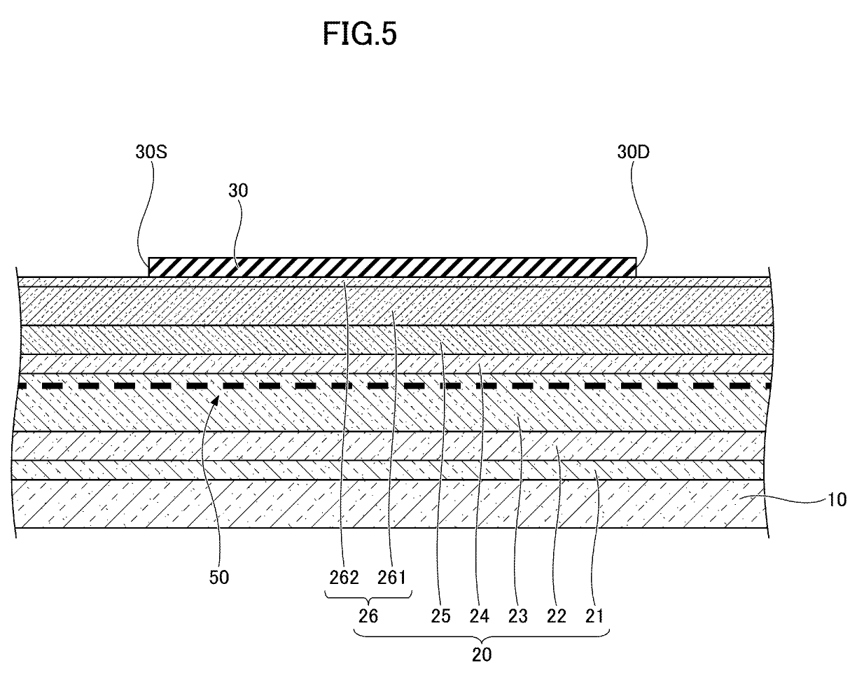

Next, as illustrated in FIG. 5, the insulating film 30 is formed on the first barrier layer 26. Next, the opening 30S for source and the opening 30D for drain are formed in the insulating film 30. The opening 30S and the opening 30D can be formed by, for example, reactive ion etching (RIE) using a mask (not illustrated). In RIE, a reactive gas containing fluorine such as carbon tetrafluoride (CF₄) is used.

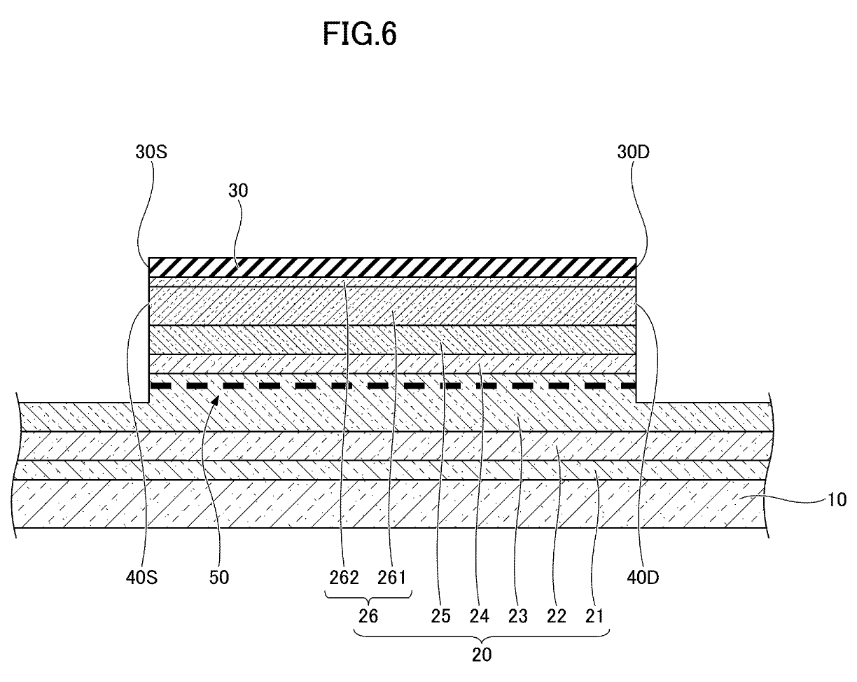

Next, as illustrated in FIG. 6, the recess 40S for source and the recess 40D for drain are formed in the nitride semiconductor layer 20. The recess 40S and the recess 40D can be formed, for example, by argon (Ar)-based ion milling using the insulating film 30 as a mask. Thereafter, the disordered portion of the crystal generated by the ion milling is removed by wet etching, chlorine-based dry etching, or both.

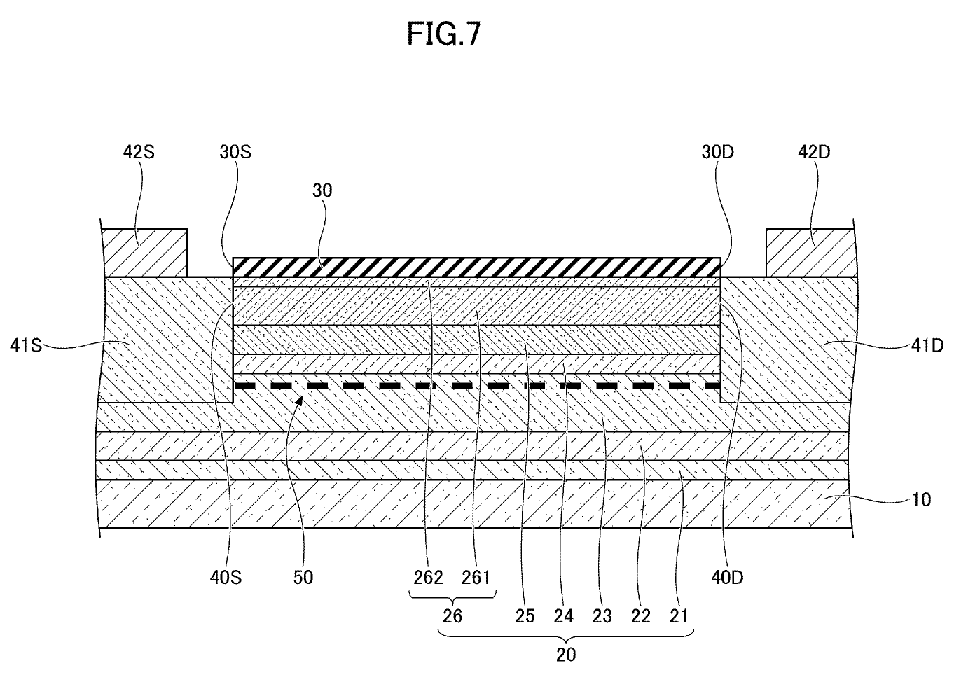

Next, as illustrated in FIG. 7, the regrowth layer 41S is formed on the channel layer 23 or the buffer layer 22 in the recess 40S, and the regrowth layer 41D is formed on the channel layer 23 or the buffer layer 22 in the recess 40D. The regrowth layer 41S and the regrowth layer 41D can be formed by, for example, the MOVPE method. To form the regrowth layer 41S and the regrowth layer 41D, trimethylgallium (TMG) and ammonia (NH₃) are used as source gases, the growth temperature is set to about 850°C, and the growth pressure is set to about 20 kPa, for example.

Next, the source electrode 42S is formed on the regrowth layer 41S, and the drain electrode 42D is formed on the regrowth layer 41D. To form the source electrode 42S and the drain electrode 42D are formed, a metal layer (not illustrated) is formed using a growth mask (not illustrated) having an opening formed in a region where the source electrode 42S and the drain electrode 42D are to be formed, and then the growth mask is removed together with the metal layer (not illustrated) formed on the growth mask. In other words, lift-off is performed.

Next, the opening 30G for gate is formed in the insulating film 30 (see FIG. 1). The opening 30G can be formed, for example, by RIE using a mask (not illustrated). Next, the gate electrode 43 to be in contact with the first barrier layer 26 via the opening 30G is formed on the insulating film 30 (see FIG. 1). To form the gate electrode 43, for example, a metal layer (not illustrated) is formed using a growth mask (not illustrated) having an opening formed in a region where the gate electrode 43 is to be formed, and then the growth mask is removed together with the metal layer (not illustrated) formed the growth mask. In other words, lift-off is performed.

The nitride semiconductor transistor 1 can be thereby manufactured.

Hereinafter, various tests conducted by the inventor of the present application will be described, focusing on the transformation of the semiconductor layer 26X into the first barrier layer 26 as a result of annealing.

### (First Test)

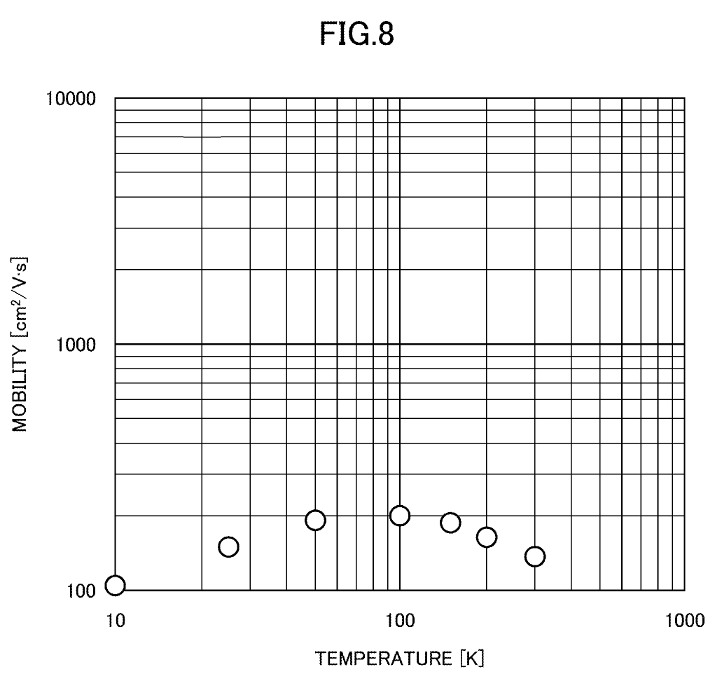

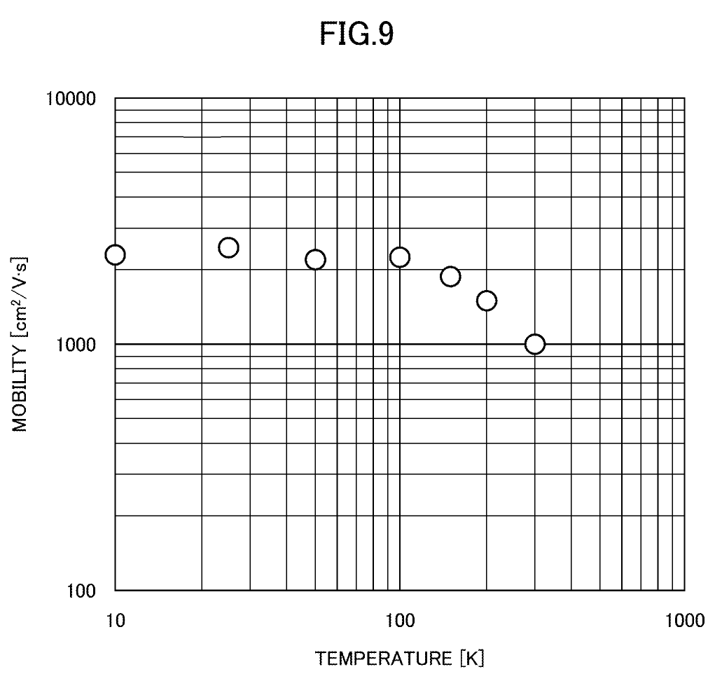

In the first test, the temperature dependence of the Hall effect before and after annealing was examined. In the first test, a sample was prepared as follows: a nucleation layer was formed on a substrate, a gallium nitride layer as a buffer layer and a channel layer was formed on the nucleation layer, a spacer layer was formed on the gallium nitride layer, a second barrier layer was formed on the spacer layer, and a first barrier layer was formed on the second barrier layer. The buffer layer, channel layer, spacer layer, and second barrier layer were formed by an MOVPE method, and the first barrier layer was formed by a sputtering method. The spacer layer was an aluminum nitride layer having a thickness of 1 nm. The second barrier layer was an aluminum gallium nitride layer having a thickness of 3 nm and an Al composition ratio of 20%. The first barrier layer was an aluminum scandium nitride layer having a thickness of 10 nm and an Sc composition ratio of 10%. The shape of the sample in a plan view was a square shape with each side having a length of 10 mm. The mobility of carriers was measured before and after annealing. The annealing was carried out at a temperature of 800°C for 60 minutes. The results are shown in FIGS. 8 and 9. FIG. 8 shows the temperature dependence of the Hall effect before annealing, and FIG. 9 shows the temperature dependence of the Hall effect after annealing.

As shown in FIG. 8, the mobility decreased at cryogenic temperatures below 100 K before annealing. As shown in FIG. 9, the mobility did not decrease at cryogenic temperatures below 100 K after annealing, and the mobility was controlled by interfacial roughness scattering. It is considered that this suggest that the carrier scattering due to ionized impurities occurred before annealing, whereas the ionized impurities decreased after annealing and the carrier scattering became less likely to occur.

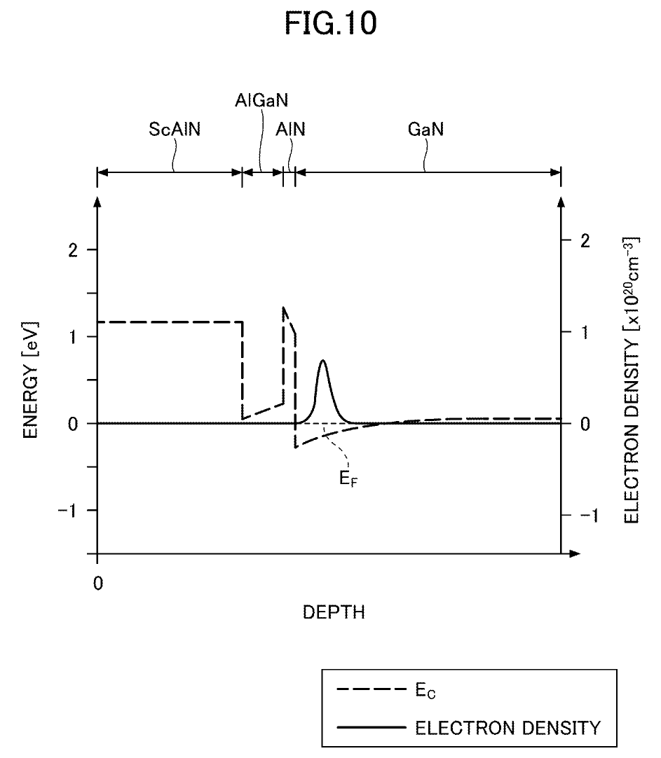

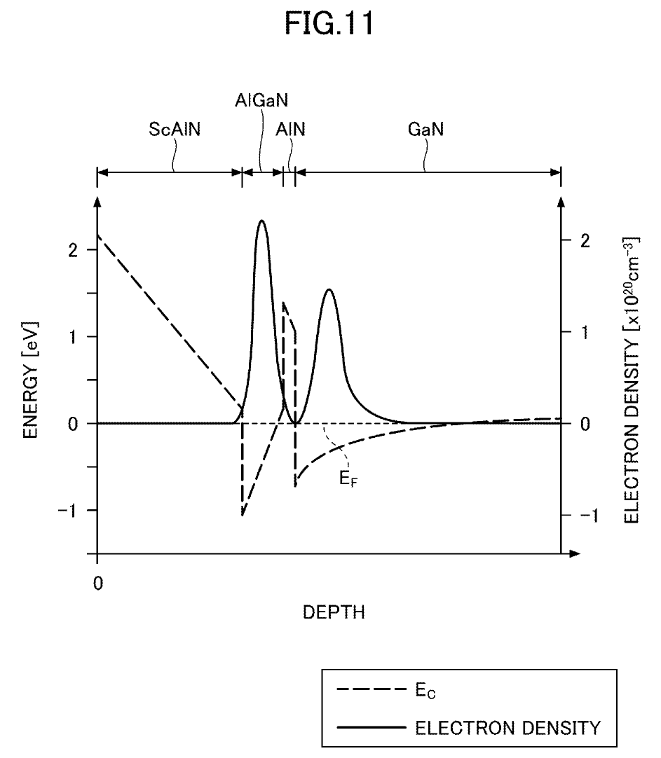

Furthermore, it is considered that the results also suggest that the ionized impurities acted as negative fixed charge, and the band structure changed. FIG. 10 illustrates the band structure before annealing, and FIG. 11 illustrates the band structure after annealing. FIGS. 10 and 11 illustrate the Fermi level E_{F} and the lower end E_{C} of the conduction band. FIGS. 10 and 11 also illustrate the electron density.

Before annealing, the first barrier layer has negative fixed charge, and the two-dimensional electron gas is remotely Coulomb scattered by negative fixed charge. The band of the first barrier layer is raised due to negative fixed charge, as illustrated in FIG. 10. After annealing, on the other hand, negative fixed charge in the first barrier layer decreases, and the two-dimensional electron gas is less susceptible to remote Coulomb scattering. Since the band of the first barrier layer is pushed down as illustrated in FIG. 11, the concentration of the two-dimensional electron gas increases.

### (Second Test)

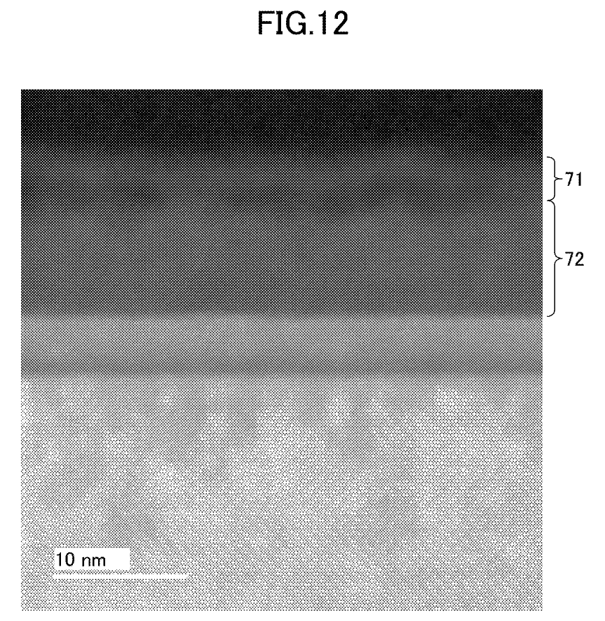

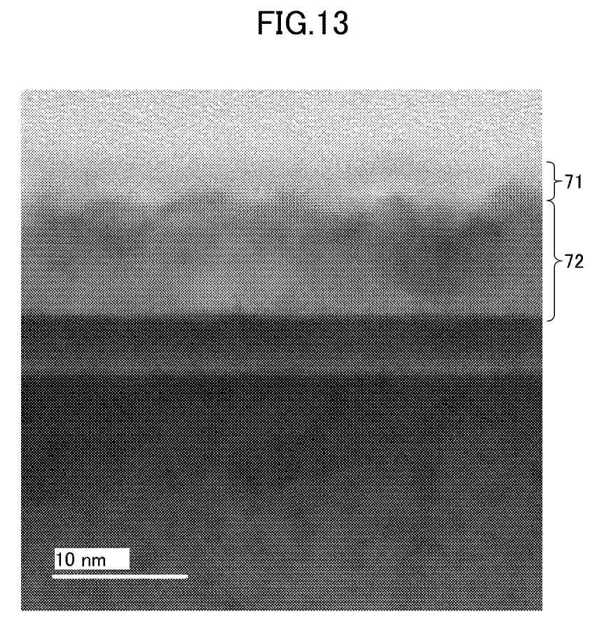

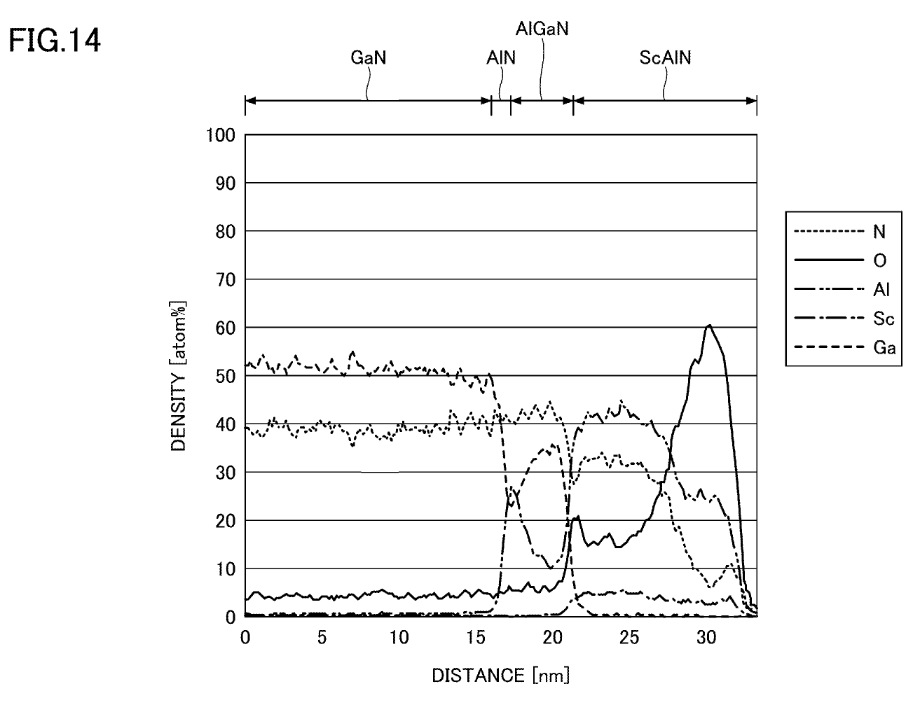

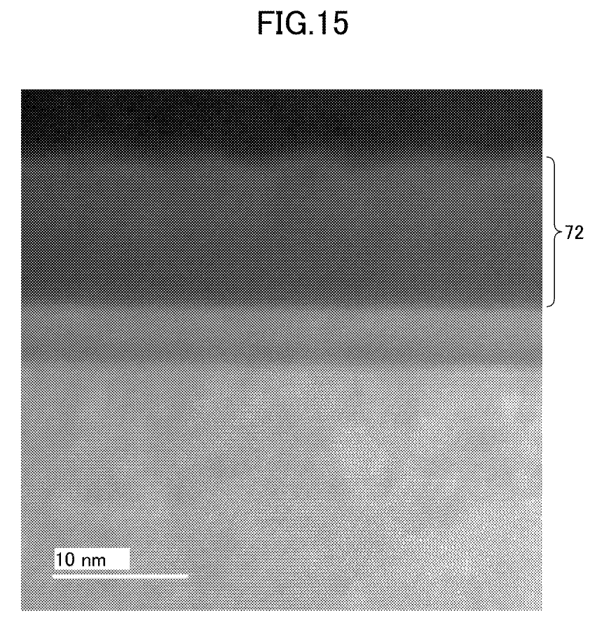

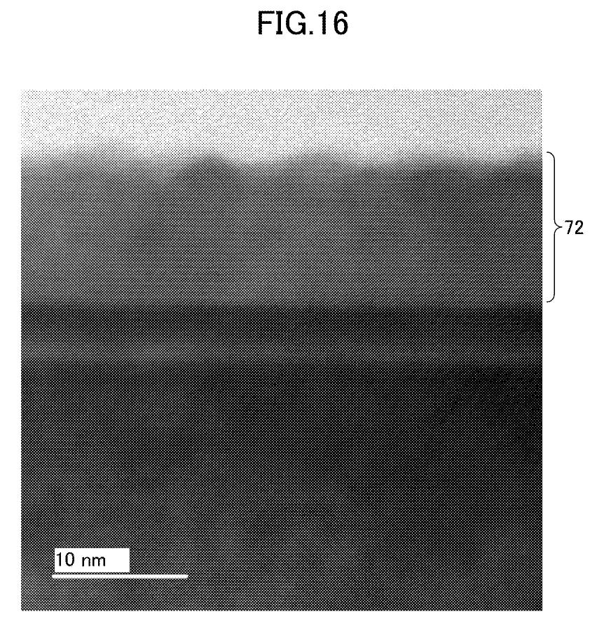

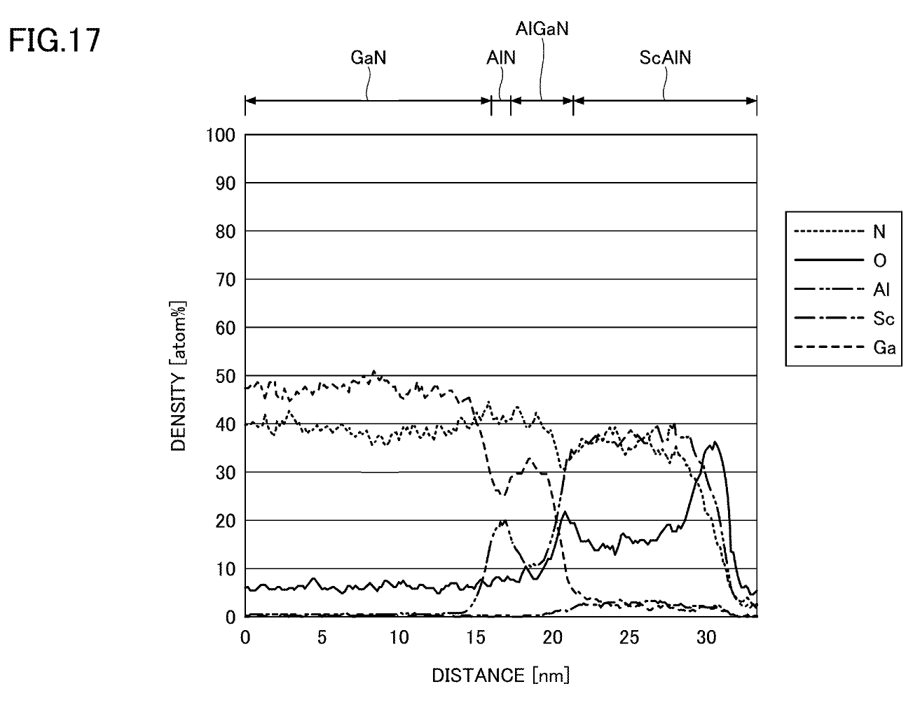

In the second test, cross-sectional observation by scanning transmission electron microscopy (STEM) and analysis by energy dispersive X-ray spectroscopy (EDX) were performed before and after the annealing. In the second test, a sample was prepared in the same manner as in the first test. Next, a carbon film as a protective layer was formed on the second barrier layer by sputtering. Next, the stack was processed by a focused ion beam machine so that a cross-section perpendicular to the stacking direction of the sample and the carbon film would appear. In the cross-sectional observation by STEM, an annular dark field (ADF) images and bright field (BF) images were obtained. The results of the second test are shown in FIGS. 12 through 17. FIG. 12 shows an ADF image before annealing, FIG. 13 shows a BF image before annealing, and FIG. 14 shows the results of EDX analysis before annealing. FIG. 15 shows an ADF image after annealing, FIG. 16 shows a BF image after annealing, and FIG. 17 shows the results of EDX analysis after annealing. In FIGS. 14 and 17, the 0 nm position is defined as 33 nm from the outermost surface of the aluminum scandium nitride layer, which serves as the first barrier layer.

As shown in FIGS. 12 and 13, the first barrier layer had an amorphous region 71 and a crystalline region 72 before annealing. The region 72 was present below the region 71. As shown in FIG. 14, the maximum oxygen concentration in the amorphous region 72 was as great as about 60 at.%.

On the other hand, as shown in FIGS. 15 and 16, the amorphous region 71 was transformed into the crystalline region 72 after annealing. A region in which the oxygen concentration was greater than 20 at.% was present in the region 72 as illustrated in FIG. 17, but the maximum oxygen concentration was equal to or less than 40 at.%.

In FIGS. 14 and 17, the decrease in the concentrations of scandium, aluminum, and nitrogen in the surface layer of the ScAlN layer is due to errors in EDX analysis. The increase in the concentration of oxygen in the vicinity of the boundary between the AlGaN layer and the ScAlN layer around the boundary is due to slight oxidation of the surface of the AlGaN layer formed by the MOVPE method before the formation of the ScAlN layer by the sputtering method.

### (Third Test)

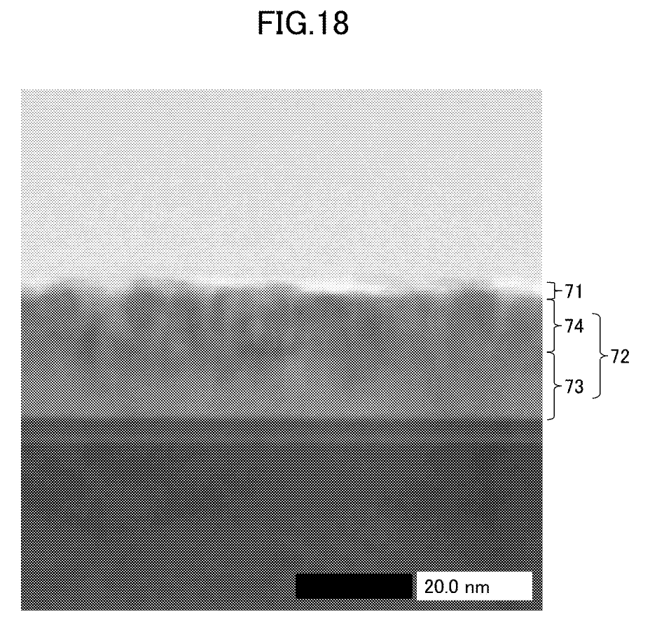

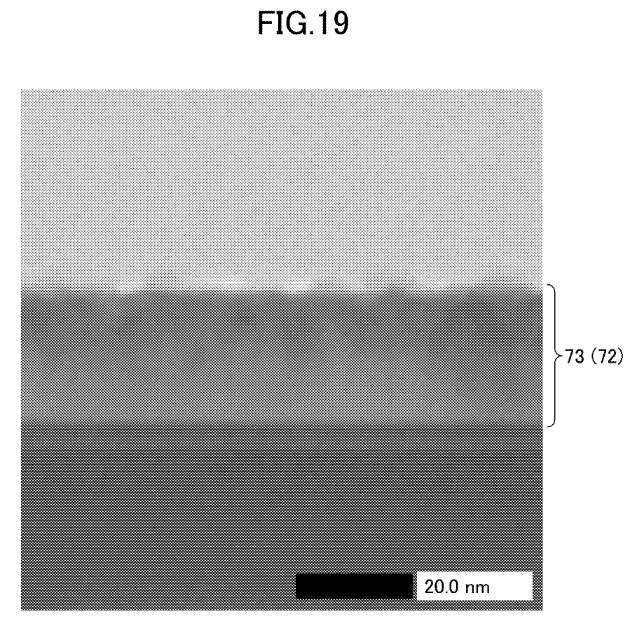

In the third test, an aluminum scandium nitride layer was formed as the first barrier layer under sputtering conditions differing from the first test, and TEM observation was performed before and after annealing. The results are shown in FIGS. 18 and 19. FIG. 18 shows a TEM observation image before annealing, and FIG. 19 shows a TEM observation image after annealing.

As shown in FIG. 18, the first barrier layer before subjected to annealing had an amorphous region 71 and a crystalline region 72. In the region 72, a region 73 and a region 74 having more crystal grains than the region 73 were present. The region 73 was present below the region 74. As shown in FIG. 19, the amorphous region 71 was transformed into the crystalline region 72 after annealing, and the region 74 having more crystal grains was transformed into the region 73 after annealing.

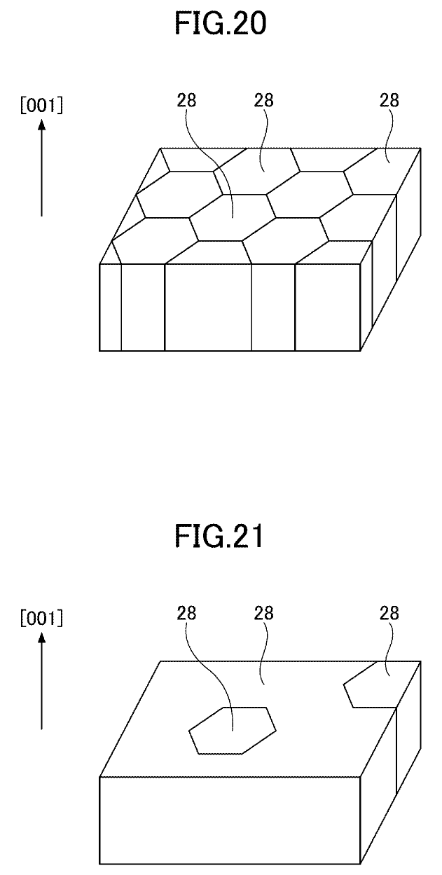

Such a transformation in the structure of the region 72 is considered to be caused by the phenomenon described below. FIGS. 20 and 21 are schematic diagrams illustrating the structural transformation of the crystalline regions before and after annealing.

Before annealing, there are many crystal grains 28 in the region 74 as illustrated in FIG. 20, but annealing promotes the coarsening of the crystal grains 28, and the number of crystal grains 28 decreases as a result of annealing as illustrated in FIG. 21. Moreover, such a structural transformation leads to decrease in the oxygen concentration in the first barrier layer. In other words, oxygen atoms can be present both inside the grains 28 and at the grain boundaries; however, when annealing is performed, the grain boundaries decrease, and the oxygen atoms existing at the grain boundary are released to the outside. In addition, the oxygen atoms in the grains 28 act as positive fixed charge, and the oxygen atoms at the grain boundaries act as negative fixed charge. The release of the oxygen atoms at the grain boundaries makes the remote Coulomb scattering of the two-dimensional electron gas difficult to occur.

### (Fourth Test)

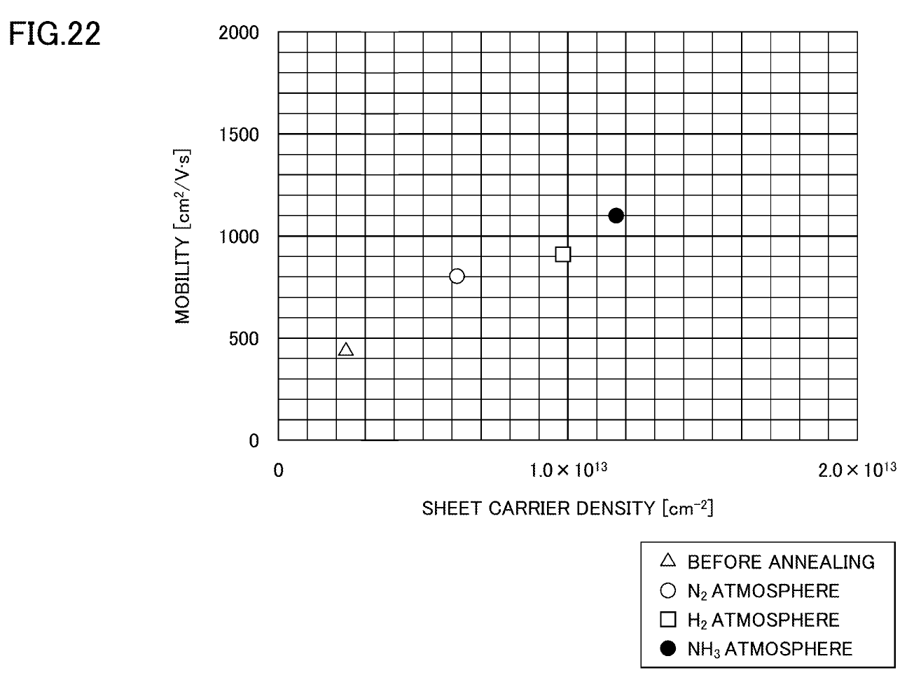

In the fourth test, annealing atmospheres were examined. Specifically, annealing was carried out in 3 types of atmospheres: nitrogen (N₂) atmosphere, hydrogen (H₂) atmosphere, and ammonia (NH₃) atmosphere, and the sheet carrier concentration and the mobility were measured. The pre-annealing sheet carrier concentration and mobility were also measured for reference. The results are shown in FIG. 22. FIG. 22 is a graph showing a relationship between the sheet carrier concentration and the mobility in the different annealing atmospheres.

As shown in FIG. 22, the sheet carrier concentration and the sheet carrier mobility were increased after annealing in all three atmospheres, compared to their pre-annealing values. In the hydrogen atmosphere, the sheet carrier concentration and the mobility were greater than those in the nitrogen atmosphere. This is because hydrogen has a reducing action and the oxygen concentration of the first barrier layer tends to decrease. In the ammonia atmosphere, the sheet carrier concentration and the mobility were greater than those in the hydrogen atmosphere. This is because ammonia has a reducing action similar to that of hydrogen and also because nitrogen atoms in ammonia enter into the nitrogen vacancies of the first barrier layer, thereby reducing the nitrogen vacancies.

In the nitride semiconductor transistor 1, the first barrier layer 26 formed by a sputtering method unavoidably has a first region 261 having a first oxygen concentration equal to or less than 20 at.% and a second region 262 having a second oxygen concentration greater than 20 at.%. Since the maximum value of the second oxygen concentration is equal to or less than 50 at.%, negative fixed charge contained in the first barrier layer 26 is small, and the sheet resistance can be reduced. When the maximum value of the second oxygen concentration is equal to or less than 40 at.%, the sheet resistance is particularly easy to be reduced. The maximum value of the second oxygen concentration may be equal to or less than 35 at.%. The first oxygen concentration and the second oxygen concentration can be measured by energy dispersive X-ray spectroscopy.

Since the nitride semiconductor transistor 1 has the second barrier layer 25, it is easy to increase the concentration of the two-dimensional electron gas 50 and further reduce the sheet resistance.

The rare earth group III element contained in the first barrier layer 26 is not limited to scandium. However, scandium has a relatively small ionic radius among the rare earth group III elements, and nitrides of scandium and aluminum can have a smaller lattice mismatch with gallium nitride than when other rare earth group III elements are contained. For this reason, in the case where the first barrier layer 26 contains scandium as a rare earth group III element, for example, the crystallinity of the nitride semiconductor layer 20 including the channel layer 23 and the first barrier layer 26 can be improved.

In the case where the first barrier layer 26 is an aluminum scandium nitride layer, it is easy to increase the concentration of the two-dimensional electron gas 50 when the Sc composition ratio in the first barrier layer 26 is equal to or greater than 5%. When the Sc composition ratio is equal to or less than 45%, the first barrier layer 26 tends to have a wurtzite crystal structure. In general, the greater the Sc composition ratio, the greater the relative dielectric constant of aluminum scandium nitride, which tends to cause remote Coulomb scattering. However, in the present embodiment, since the maximum value of the second oxygen concentration is equal to or less than 50 at.%, the sheet resistance can be reduced.

In the method for manufacturing the nitride semiconductor transistor 1, when the semiconductor layer 26X is formed at a temperature of 700°C or lower, the semiconductor layer 26X tends to have a wurtzite crystal structure. When the semiconductor layer 26X is formed at a temperature higher than 700°C, the semiconductor layer 26X may undergo phase separation into a Sc-rich phase exhibiting a rock-salt crystal structure and an Al-rich phase exhibiting a wurtzite crystal structure.

In the case where the annealing temperature is higher than the temperature at which the semiconductor layer 26X is formed, the crystallinity of the semiconductor layer 26X is enhanced and the oxygen concentration in the semiconductor layer 26X is easily reduced. However, when the annealing temperature is higher than 1,000°C, the semiconductor layer 26X may undergo phase separation into a Sc-rich phase exhibiting a rock-salt crystal structure and an Al-rich phase exhibiting a wurtzite crystal structure. When the annealing temperature is 1,000°C or lower, it is possible to make the phase separation caused by annealing less likely to occur in the semiconductor layer 26X.

The annealing atmosphere is not limited to a particular type, and the annealing is performed in an atmosphere containing at least one gas selected from nitrogen gas, hydrogen gas, and ammonia gas. For example, the mixed gas may have a nitrogen-to-hydrogen-to-ammonia ratio of 100:1:10. In this case, the oxygen concentration in the semiconductor layer 26X is easily reduced. In the case where the ambient gas contains hydrogen gas or ammonia gas, the oxygen concentration is easily reduced by a reduction action in particular, and in the case where the ambient gas contains ammonia gas, the nitrogen vacancies in the semiconductor layer 26X are easily reduced.

Although the embodiments have been described in detail, the present disclosure is not limited to such specific embodiments, and various modifications and changes can be made within the scope described in the claims.

What is claimed is:

1. A nitride semiconductor transistor, comprising:
a channel layer; and
a first barrier layer overlapping the channel layer, the first barrier layer containing a rare earth group III element, aluminum, and nitrogen, wherein
the first barrier layer includes
a first region having a first oxygen concentration equal to or less than 20 at.%; and
a second region having a second oxygen concentration greater than 20 at.%,
the first region is located between the channel layer and the second region,
a thickness of the first region is greater than that of the second region, and
a maximum value of the second oxygen concentration is equal to or less than 50 at.%.

2. The nitride semiconductor transistor according to claim 1, wherein
a maximum value of the second oxygen concentration is equal to or less than 40 at.%.

3. The nitride semiconductor transistor according to claim 1, further comprising:
a second barrier layer located between the channel layer and the first barrier layer, wherein
the second barrier layer contains gallium, aluminum, and nitrogen.

4. The nitride semiconductor transistor according to claim 1, wherein
the first barrier layer contains scandium as a rare earth group III element.

5. A method of manufacturing the nitride semiconductor transistor, the method comprising:
forming a channel layer and a semiconductor layer overlapping the channel layer; and
forming a first barrier layer by annealing the semiconductor layer so as to lower an oxygen concentration in the semiconductor layer, wherein
the semiconductor layer is formed by a sputtering method, and
the semiconductor layer contains a rare earth group III element, aluminum, and nitrogen.

6. The method of manufacturing the nitride semiconductor transistor according to claim 5, wherein
the semiconductor layer is formed at a temperature equal to or lower than 700°C.

7. The method of manufacturing the nitride semiconductor transistor according to claim 5, wherein
the annealing temperature is higher than the temperature at which the semiconductor layer is formed.

8. The method of manufacturing the nitride semiconductor transistor according to claim 7, wherein
the annealing temperature is equal to or lower than 1,000°C.

9. The method of manufacturing the nitride semiconductor transistor according to claim 5, wherein
the annealing is performed in an atmosphere containing at least one gas selected from nitrogen gas, hydrogen gas, and ammonia gas.
